(19) United States
(12) Patent Application Publication
(10) Pub. No.: US 2020/0146153 A1
(43) Pub. Date: May 7, 2020

(54) CORE MATERIAL MANUFACTURING METHOD AND COPPER-CLAD LAMINATE MANUFACTURING METHOD

(71) Applicant: DISCO CORPORATION, Tokyo (JP)

(72) Inventor: Katsuhiko SUZUKI, Tokyo (JP)

(21) Appl. No.: 16/668,813

(22) Filed: Oct. 30, 2019

(30) Foreign Application Priority Data
Nov. 1, 2018 (JP) 2018-206646

(51) Int. Cl. H05K 3/02

(52) U.S. Cl. CPC H05K 3/022; H05K 2203/0143; H05K 2203/068

(57) ABSTRACT

A planarized core material manufacturing method includes: a core material forming step of forming a core material having a first surface and a second surface opposed to the first surface by impregnating glass cloth with a synthetic resin, and drying the glass cloth; and a core material planarizing step of planarizing the first surface or the second surface of the core material by grinding processing or polishing processing. Preferably, a plurality of pieces of the glass cloth are laminated in the core material.

### BACKGROUND OF THE INVENTION

### Field of the Invention

The present invention relates to a method of manufacturing a planarized core material used in manufacturing a copper-clad laminate and a method of manufacturing the copper-clad laminate using the planarized core material.

### Description of the Related Art

A device chip used in electronic equipment such as a mobile telephone, a personal computer, or the like is bonded onto a printed board, and is ultimately incorporated into the electronic equipment. A copper-clad laminate is widely used for the printed board. The copper-clad laminate is manufactured by the following method, for example. First, glass cloth is prepared, the glass cloth is impregnated with a synthetic resin (varnish), and the glass cloth is dried. Next, the glass cloth is cut into a predetermined size. Each piece cut and formed in the predetermined size becomes a core material referred to as a prepreg. Then, a copper-clad laminate is formed when copper foil is superposed on both surfaces of the core material (prepreg) and the core material having the copper foil on both surfaces thereof is pressed from both surfaces while heated. Incidentally, a copper-clad laminate may be formed by laminating a plurality of pieces of core material (prepreg), and thereafter superposing copper foil on both surfaces. Then, a printed board serving as a device chip mounting board can be formed when a wiring layer is formed on the basis of the copper foil on one or both surfaces of the formed copper-clad laminate (see Japanese Patent Laid-Open No. S56-118853 and Japanese Patent Laid-Open No. S59-39546).

A mounting technology referred to as flip chip bonding has recently been put to practical use for saving the space of a region needed for mounting when the device chip is mounted on the printed board. In flip chip bonding, a plurality of metallic projections referred to as bumps having a height of approximately 10 to 100 μm are formed on the top surface side of a device, and these bumps are made to face electrodes formed on the printed board and are directly bonded to the electrodes. That is, the bumps function as terminals of the device chip.

### SUMMARY OF THE INVENTION

The glass cloth serving as a material for the core material is formed by weaving glass fiber. Unevenness resulting from the shape of the glass fiber and the weaving of the glass fiber is present on the top surface and undersurface of the core material formed by the above-described method. An uneven shape is therefore present also on the top surface and undersurface of the copper-clad laminate manufactured by the above-described method. When the uneven shape is present on a mounting surface at a time of bonding the device chip to the printed board formed of the copper-clad laminate, the terminals of the device chip may not be bonded properly. Such a problem is referred to as a bonding failure.

It is accordingly an object of the present invention to provide a method of manufacturing a planarized core material useable in manufacturing a copper-clad laminate that can suppress a bonding failure of a device chip and the copper-clad laminate using the planarized core material.

In accordance with an aspect of the present invention, there is provided a planarized core material manufacturing method including: a core material forming step of forming a core material having a first surface and a second surface opposed to the first surface by impregnating glass cloth with a synthetic resin, and drying the glass cloth; and a core material planarizing step of planarizing the first surface or the second surface of the core material by grinding processing or polishing processing. Preferably, a plurality of pieces of the glass cloth are laminated in the core material.

In addition, according to another mode of the present invention, there is provided a copper-clad laminate manufacturing method including: a core material preparing step of preparing a core material having a first surface and a second surface opposed to the first surface, and formed by impregnating glass cloth with a synthetic resin and drying the glass cloth; a core material planarizing step of planarizing the first surface or the second surface of the core material by grinding processing or polishing processing; and a copper-clad laminate forming step of forming a copper-clad laminate by disposing copper foil on one or both of the first surface and the second surface of the core material, and pressing the core material and the copper foil while heating the core material and the copper foil. Preferably, a plurality of pieces of the glass cloth are laminated in the core material.

Further, according to another mode of the present invention, there is provided a copper-clad laminate manufacturing method including: a core material preparing step of preparing a core material having a first surface and a second surface opposed to the first surface, and formed by impregnating glass cloth with a synthetic resin and drying the glass cloth; a core material planarizing step of planarizing one or both of the first surface and the second surface of the core material by polishing processing; and a copper-clad laminate forming step of forming a copper-clad laminate by disposing copper foil on one or both of the first surface and the second surface of the core material, and pressing the core material and the copper foil while heating the core material and the copper foil, in which, in the core material planarizing step, a cylindrical polishing roller is prepared, and the polishing processing is performed by holding the polishing roller in contact with the core material while rotating the polishing roller. Preferably, a plurality of pieces of the glass cloth are laminated in the core material.

In one mode of the present invention, a core material having a first surface and a second surface is formed by impregnating glass cloth with a synthetic resin and drying the glass cloth, and the first surface or the second surface of the formed core material is planarized by grinding. Thereafter, a copper-clad laminate can be formed when copper foil is disposed on one or both of the first surface and the second surface of the core material, and the core material and the copper foil are pressed against each other while heated. At least one surface of the core material is planarized, and variations in partial thickness of the core material are reduced. Thus, uneven shapes of the top surface and undersurface of the formed copper-clad laminate are reduced as compared with a case where the core material is not planarized. It is therefore possible to suppress the occurrence of a bonding failure at a time of bonding a device chip to the copper-clad laminate.

Hence, the present invention provides a method of manufacturing a planarized core material useable in manufacturing a copper-clad laminate that can suppress a bonding failure of a device chip and the copper-clad laminate using the planarized core material.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a diagram schematically illustrating the formation of a core material;

FIG. 2 is a perspective view schematically illustrating a grinding apparatus;

FIG. 3 is a sectional view schematically illustrating a step of planarizing one surface of the core material;

FIG. 4A is a side view schematically illustrating the core material and copper foil;

FIG. 4B is a side view schematically illustrating a copper-clad laminate forming step;

FIG. 4C is a perspective view schematically illustrating a copper-clad laminate;

FIG. 5A is a perspective view schematically illustrating a polishing apparatus including a polishing roller; and

FIG. 5B is a side view schematically illustrating the polishing apparatus including the polishing roller.

### DETAILED DESCRIPTION OF THE PREFERRED EMBODIMENT

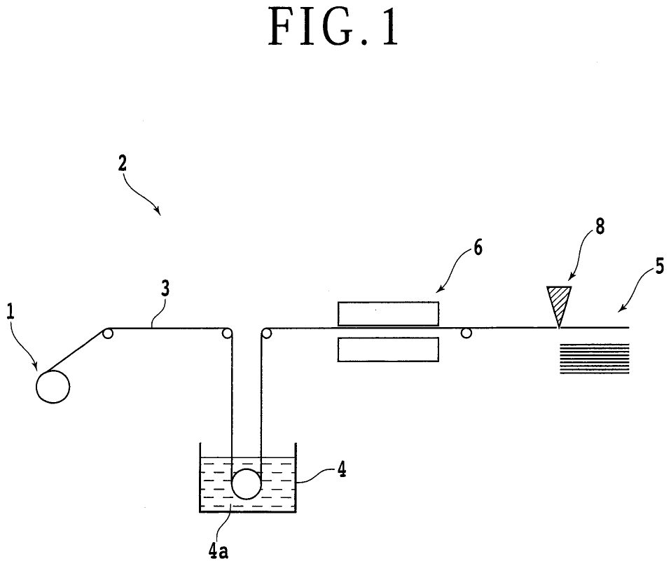

An embodiment of the present invention will be described with reference to the accompanying drawings. The formation of a core material (prepreg) planarized by a manufacturing method according to the present embodiment will first be described with reference to FIG. 1. FIG. 1 is a diagram schematically illustrating the formation of a core material.

A core material 5 is, for example, manufactured by using a core material manufacturing apparatus 2 illustrated in FIG. 1. The core material manufacturing apparatus 2 includes an impregnating vat 4 storing a liquid synthetic resin (varnish), a heating apparatus 6, and a cutting apparatus 8. The core material 5 is formed of glass cloth formed by weaving glass fiber. A glass cloth roll 1 having glass cloth wound in a roll shape is placed in the core material manufacturing apparatus 2, and a band-shaped glass cloth 3 is pulled out from the glass cloth roll 1. Then, the glass cloth 3 is passed in a synthetic resin 4a of the impregnating vat 4 to impregnate the glass cloth 3 with the synthetic resin 4a. Incidentally, the synthetic resin 4a is a resin in a state before curing, the resin being, for example, an epoxy resin, a phenolic resin, a polyetheretherketone (PEEK) resin, or the like. Next, the glass cloth 3 impregnated with the synthetic resin 4a is passed through the heating apparatus 6. The heating apparatus 6 heats and dries the glass cloth 3, and cures the synthetic resin 4a impregnated with the glass cloth 3. The cutting apparatus 8 thereafter cuts the glass cloth 3 into a predetermined size. Then, the core material 5 is formed. Incidentally, the core material 5 may be formed by laminating a plurality of pieces of glass cloth 3. FIG. 1 illustrates a case where the core material 5 is formed of a single-layer glass cloth 3 and a case where the core material 5 is formed by laminating a plurality of pieces of glass cloth 3.

The formed core material 5 has a first surface and a second surface opposed to the first surface. A copper foil is disposed on one or both of the first surface and the second surface of the formed core material 5, and a copper-clad laminate can be formed when the core material 5 and the copper foil are pressed against each other while heated. Here, the glass cloth 3 is formed by weaving glass fiber. Unevenness resulting from the shape of the glass fiber and the weaving of the glass fiber is present on the first surface and the second surface of the core material 5 formed by the above-described method. An uneven shape is therefore present also on the top surface and undersurface of the copper-clad laminate manufactured by the above-described method. Accordingly, a core material manufacturing method according to the present embodiment planarizes the first surface or the second surface of the core material 5 before disposing the copper foil on the core material 5 and pressing the core material 5 and the copper foil while heating the core material 5 and the copper foil. The size of the uneven shape on the planarized core material 5 is reduced as compared with the core material 5 before being planarized. In this case, the size of the uneven shape of the subsequently formed copper-clad laminate is also reduced.

Description will next be made of each step of the method of manufacturing the planarized core material according to the present embodiment. In the method of manufacturing the planarized core material, a preparing step is performed which prepares the core material 5 formed by impregnating glass cloth with a synthetic resin and drying the glass cloth. The preparing step prepares the core material 5 manufactured by the above-described method.

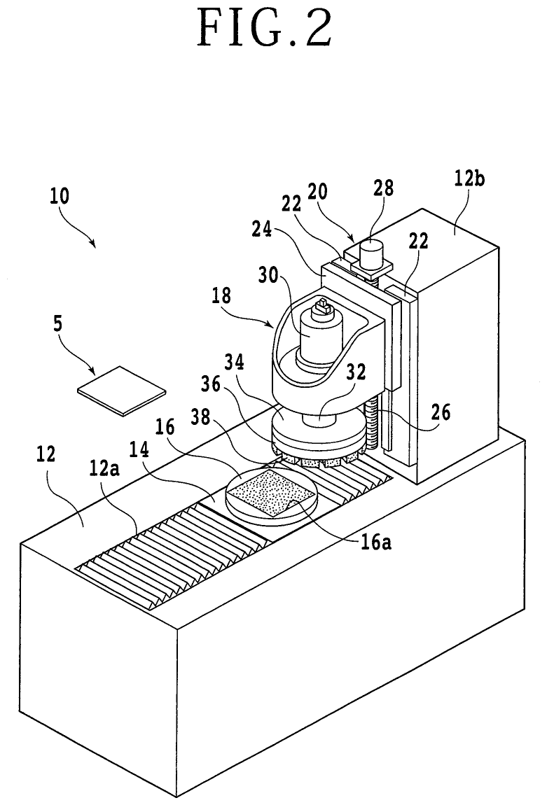

Next, in the manufacturing method according to the present embodiment, a core material planarizing step is performed which planarizes the core material 5 by grinding processing. The core material planarizing step is performed by a grinding apparatus illustrated in FIG. 2, for example. FIG. 2 is a perspective view schematically illustrating the grinding apparatus. The grinding apparatus 10 used in the core material planarizing step has a base 12 supporting each configuration. An opening 12a is provided in an upper surface of the base 12. Provided within the opening 12a is an X-axis moving table 14 having a chuck table 16 mounted on a top surface thereof, the chuck table 16 sucking and holding the core material 5. The X-axis moving table 14 is movable in an X-axis direction by an X-axis direction moving mechanism not illustrated. The top surface of the chuck table 16 serves as a holding surface 16a that holds the core material 5. The chuck table 16 internally includes a suction passage having one end communicating with the holding surface 16a of the chuck table 16 and having another end connected to a suction source not illustrated. When the suction source is actuated, a negative pressure acts on the core material 5 mounted on the holding surface 16a, so that the core material 5 is sucked and held on the chuck table 16. In addition, the chuck table 16 is rotatable about an axis along a direction perpendicular to the holding surface 16a.

A grinding unit 18 that grinds the core material 5 is disposed above the chuck table 16. A supporting portion 12b is erected on a rear end portion of the base 12 of the grinding apparatus 10. The supporting portion 12b supports the grinding unit 18. The grinding unit 18 is movable in a vertical direction by a Z-axis moving mechanism 20 disposed on a front surface of the supporting portion 12b. The Z-axis moving mechanism 20 includes: a pair of Z-axis guide rails 22 extending in a Z-axis direction on the front surface of the supporting portion 12b; and a Z-axis moving plate 24 slidably attached to each of the Z-axis guide rails 22. A nut portion (not illustrated) is provided on a back surface side (rear surface side) of the Z-axis moving plate 24. A Z-axis ball screw 26 parallel with the Z-axis guide rails 22 is screwed into the nut portion. A Z-axis pulse motor 28 is coupled to one end portion of the Z-axis ball screw 26. When the Z-axis ball screw 26 is rotated by the Z-axis pulse motor 28, the Z-axis moving plate 24 moves in the Z-axis direction along the Z-axis guide rails 22.

The grinding unit 18 is fixed to a lower portion on a front surface side of the Z-axis moving plate 24. The grinding unit 18 can be moved in the Z-axis direction when the Z-axis moving plate 24 is moved in the Z-axis direction. The grinding unit 18 includes: a spindle 32 rotated by a motor coupled to a base end side of the spindle 32; and a grinding wheel 36 fixed to a mount 34 disposed on a distal end side of the spindle 32. The motor is included within a spindle housing 30. When the motor is actuated, the grinding wheel 36 rotates according to rotation of the spindle 32. A grinding stone 38 is provided to an undersurface of the grinding wheel 36. The core material 5 is ground when the grinding wheel 36 is rotated by rotating the spindle 32, the grinding unit 18 is lowered along the Z-axis direction, and a lower end of the grinding stone 38 is brought into contact with the core material 5. A ground surface of the core material 5 is planarized when the grinding unit 18 is lowered to a predetermined height position. The grinding stone 38 is formed by dispersing abrasive grains into a binder. The core material manufacturing method according to one mode of the present invention preferably uses the grinding stone 38 whose grain size (#) is approximately 320 to 600. There is a fear of causing loading or the like during the grinding processing when a grinding stone having an excessively small grain size is used.

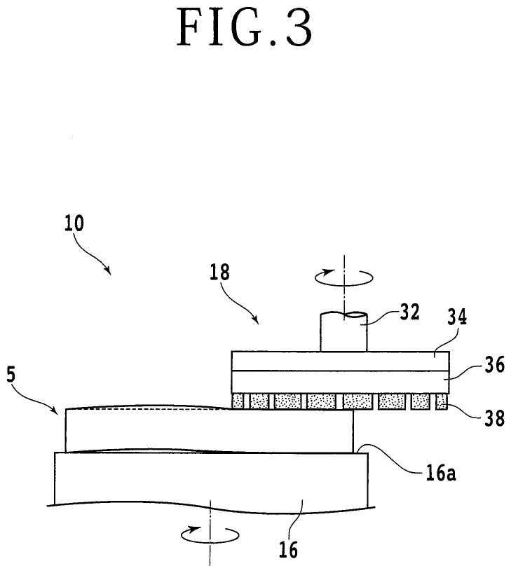

In the core material planarizing step, first, the core material 5 is placed on the holding surface 16a of the chuck table 16, and the chuck table 16 is made to suck and hold the core material 5 by actuating the suction source (not illustrated) of the chuck table 16. Next, the X-axis moving table 14 is moved to a position below the grinding unit 18. Then, the grinding wheel 36 is lowered while the chuck table 16 and the grinding wheel 36 are rotated. FIG. 3 is a sectional view schematically illustrating a step of planarizing the first surface of the core material. As illustrated in FIG. 3, the first surface is ground when the grinding stone 38 fitted to the grinding wheel 36 is in contact with the first surface of the core material 5. The first surface is thus planarized.

Incidentally, in the core material planarizing step, the second surface may be ground in place of the first surface of the core material 5. When the first surface or the second surface of the core material is planarized by the grinding processing, the core material 5 that is planarized and whose uneven shape is therefore reduced in size is obtained. When the planarized core material 5 is used to form a copper-clad laminate, a flat copper-clad laminate can be formed. A mounting defect does not occur easily when a printed board is formed of the flat copper-clad laminate and a device chip is bonded to the printed board. The core material 5 is, for example, formed with a thickness of approximately 400 to 800 μm, and one of the first surface and the second surface is ground by approximately 20 to 40 μm by the grinding processing. That is, a thickness of approximately 5% with respect to the thickness of the core material 5 is removed from each surface of the core material 5 by the grinding processing.

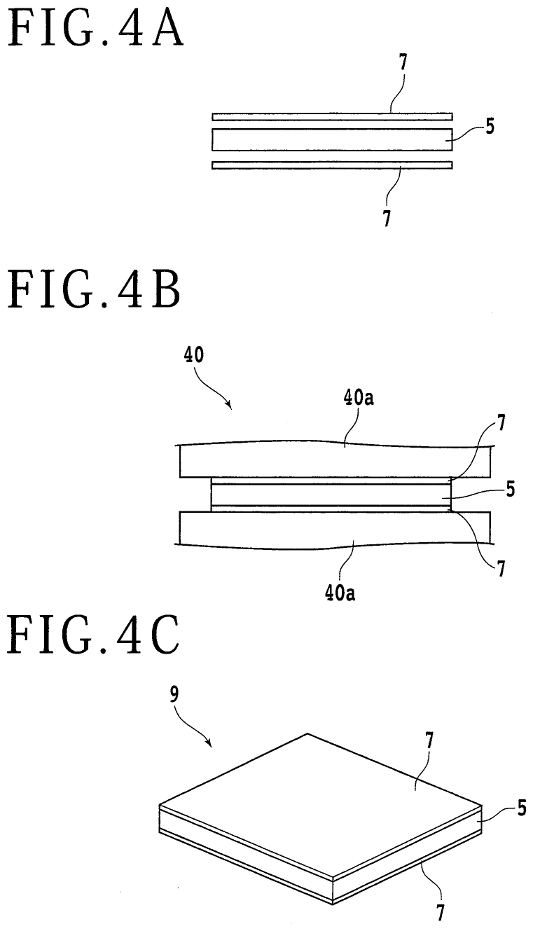

Description will next be made of a method of forming a copper-clad laminate having a flat top surface and a flat undersurface. In a method of manufacturing the copper-clad laminate, first, a planarized core material preparing step is performed which prepares the planarized core material manufactured by the planarized core material manufacturing method described above. Next, a copper-clad laminate forming step is performed. In the copper-clad laminate forming step, first, copper foil is disposed on one or both of the first surface and the second surface of the planarized core material 5. The following description will be made by taking as an example a case where the copper foil is disposed on both of the first surface and the second surface. FIG. 4A is a side view schematically illustrating the planarized core material and the copper foil. The copper foil 7 disposed on both surfaces of the core material 5 is formed in a planar shape similar to that of the core material 5.

Next, the core material 5 provided with the copper foil 7 on both surfaces thereof is pressed from both the surfaces while heated. A heating and pressing apparatus 40 illustrated in FIG. 4B, for example, is used to heat and press the core material 5. Here, FIG. 4B is a side view schematically illustrating the copper-clad laminate forming step. The heating and pressing apparatus 40, for example, includes a pair of upper and lower pressing plates 40a, and has a function of moving the pair of pressing plates 40a in directions of approaching each other. A heating apparatus such as a heater or the like is disposed within one or both of the pair of pressing plates 40a. When the core material 5 is to be pressed from both surfaces while heated, the core material 5 having the copper foil 7 disposed on both surfaces thereof is carried in to a position between the pair of pressing plates 40a, and the pair of pressing plates 40a is moved in directions of approaching each other while the heating apparatus is operated. Then, the core material 5 is pressed while heated, so that the copper foil 7 is affixed to the core material 5. A copper-clad laminate is thus formed.

The formed copper-clad laminate is illustrated in FIG. 4C. FIG. 4C is a perspective view schematically illustrating the copper-clad laminate. When the copper-clad laminate forming step is performed, a copper-clad laminate 9 having the copper foil 7 affixed to both surfaces of the planarized core material 5 is formed. Incidentally, in the core material planarizing step, the size of uneven shapes of both surfaces may be reduced by grinding both of the first surface and the second surface of the core material 5. However, when the core material is planarized by grinding both surfaces, the core material (copper-clad laminate) manufacturing step takes more time as compared with a case where the grinding processing is performed on only one surface.

In a case where the occurrence of a bonding failure can be suppressed sufficiently by grinding only one surface of the core material 5 and thus reducing the size of the uneven shape, the time taken for the core material manufacturing step can be shortened by performing the grinding processing on one surface. However, the core material manufacturing method and the copper-clad laminate manufacturing method according to the present embodiment are not limited to the case of grinding only one surface of the core material 5. While description has been made of the case where the core material is ground by the grinding apparatus in the core material planarizing step, the core material 5 may be planarized by another method in the core material planarizing step. For example, the core material 5 may be planarized by polishing processing in place of the grinding processing. In the following, description will be made of a case where the first surface or the second surface of the core material 5 is planarized by the polishing processing in the core material planarizing step.

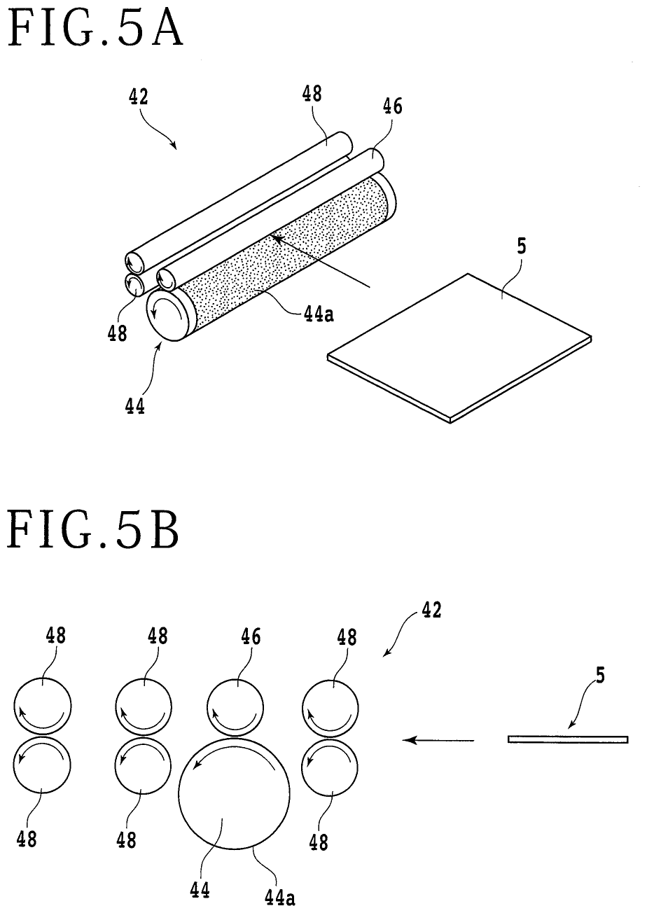

A polishing apparatus used in the core material planarizing step will be described. FIG. 5A is a perspective view schematically illustrating a configuration of a part of a polishing apparatus 42. FIG. 5B is a side view schematically illustrating a configuration of a part of the polishing apparatus 42. The polishing apparatus 42 illustrated in FIG. 5A and FIG. 5B is a roller polishing apparatus. However, the polishing apparatus used in the core material planarizing step is not limited to the roller polishing apparatus, but may be a polishing apparatus including a polishing pad having a flat polishing surface. The polishing apparatus 42, for example, includes a cylindrical polishing roller 44 and a backup roller 46 disposed above the polishing roller 44. A polishing cloth, for example, is disposed on a side surface 44a of the polishing roller 44. The polishing cloth abuts against the core material 5, and polishes the core material 5. In addition, the polishing apparatus 42 includes a plurality of conveying rollers 48 that convey the core material 5. The core material 5 is conveyed by being sandwiched between a pair of conveying rollers 48 arranged vertically.

FIG. 5A and FIG. 5B illustrate one set of the polishing roller 44 and the backup roller 46. In addition, FIG. 5A illustrates one set of upper and lower conveying rollers 48 forming a pair. In addition, FIG. 5B illustrates three sets of upper and lower conveying rollers 48 forming pairs. The radius of the backup roller 46 is substantially equal to the radius of the conveying rollers 48, and is smaller than the radius of the polishing roller 44. The polishing roller 44, the backup roller 46, and the conveying rollers 48 have a width larger than one side of the core material 5. A rotation-driving source not illustrated is connected to each roller.

Each roller is rotated when the core material 5 is polished in the polishing apparatus 42. At this time, the rotational direction of the rollers arranged on an upper side and the rotational direction of the rollers arranged on a lower side are made opposite to each other. At this time, a moving path of the core material 5 in the polishing apparatus 42 is formed between the rollers arranged on the upper side and the rollers arranged on the lower side. When the core material 5 is polished, the rotational speed of the backup roller 46 and the rotational speed of each conveying roller 48 are set equal to each other, whereas the rotational speed of the polishing roller 44 is set higher than that of the backup roller 46 and each conveying roller 48 for a purpose of polishing the core material 5. Then, the core material 5 is introduced into the moving path, and the core material 5 is planarized by polishing processing by holding the polishing roller 44 in contact with the first surface or the second surface of the core material 5 while rotating the polishing roller 44.

Incidentally, as illustrated in FIG. 5A and FIG. 5B, in the case where the polishing roller 44 is disposed on the lower side, the undersurface of the core material 5 is polished. On the other hand, in the polishing apparatus 42, the polishing roller 44 may be disposed on the upper side, and the backup roller 46 may be disposed on the lower side. In this case, the top surface of the core material 5 introduced into the polishing apparatus 42 is polished. The polishing apparatus 42 further includes a polishing liquid supply nozzle (not illustrated) in the vicinity of the polishing roller 44. During the polishing of the core material 5, a polishing liquid is supplied from the polishing liquid supply nozzle to the polishing roller 44 and the core material 5. Then, polishing swarf produced by the polishing of the core material 5 is taken into the polishing liquid, and removed.

As described above, the core material manufacturing method in accordance with the present embodiment manufactures the planarized core material 5. In addition, the copper-clad laminate manufacturing method according to the present embodiment manufactures the copper-clad laminate 9 using the planarized core material 5. Therefore, the formed copper-clad laminate 9 is also flat. When the copper-clad laminate 9 is planarized, the occurrence of a bonding failure is suppressed when a device chip is bonded to the copper-clad laminate 9.

It is to be noted that the present invention is not limited to the description of the foregoing embodiment, but can be modified and carried out in various manners. For example, in the foregoing embodiment, description has been made of a case where the polishing apparatus 42 including one polishing roller 44 polishes the first surface or the second surface of the core material 5 in the core material planarizing step. However, one mode of the present invention is not limited to this. For example, in the core material planarizing step, both surfaces of the core material 5 may be planarized by polishing by using a roller polishing apparatus including two polishing rollers, that is, a polishing roller disposed on the upper side of the moving path of the core material 5 and a polishing roller disposed on the lower side of the moving path. In this case, the core material planarizing step uses a roller polishing apparatus including two polishing rollers, that is, a first polishing roller polishing the first surface of the core material 5 and a second polishing roller polishing the second surface of the core material 5. In this case, the first surface and the second surface of the core material 5 can be polished in one process. Therefore, although both surfaces of the core material 5 are planarized by polishing processing, a time taken for the processing is not increased as compared with the case where one surface of the core material 5 is polished.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A planarized core material manufacturing method comprising:
a core material forming step of forming a core material having a first surface and a second surface opposed to the first surface by impregnating glass cloth with a synthetic resin, and drying the glass cloth; and
a core material planarizing step of planarizing the first surface or the second surface of the core material by grinding processing or polishing processing.

2. The planarized core material manufacturing method according to claim 1, wherein
a plurality of pieces of the glass cloth are laminated in the core material.

3. A copper-clad laminate manufacturing method comprising:
a core material preparing step of preparing a core material having a first surface and a second surface opposed to the first surface, and formed by impregnating glass cloth with a synthetic resin and drying the glass cloth;
a core material planarizing step of planarizing the first surface or the second surface of the core material by grinding processing or polishing processing; and
a copper-clad laminate forming step of forming a copper-clad laminate by disposing copper foil on one or both of the first surface and the second surface of the core material, and pressing the core material and the copper foil while heating the core material and the copper foil.

4. The copper-clad laminate manufacturing method according to claim 3, wherein
a plurality of pieces of the glass cloth are laminated in the core material.

5. A copper-clad laminate manufacturing method comprising:
a core material preparing step of preparing a core material having a first surface and a second surface opposed to the first surface, and formed by impregnating glass cloth with a synthetic resin and drying the glass cloth;
a core material planarizing step of planarizing one or both of the first surface and the second surface of the core material by polishing processing; and
a copper-clad laminate forming step of forming a copper-clad laminate by disposing copper foil on one or both of the first surface and the second surface of the core material, and pressing the core material and the copper foil while heating the core material and the copper foil, wherein
in the core material planarizing step, a cylindrical polishing roller is prepared, and the polishing processing is performed by holding the polishing roller in contact with the core material while rotating the polishing roller.

6. The copper-clad laminate manufacturing method according to claim 5, wherein
a plurality of pieces of the glass cloth are laminated in the core material.
